(19) United States
(12) Patent Application Publication
(10) Pub. No.: US 2010/0047717 A1
(43) Pub. Date: Feb. 25, 2010

(54) METHOD FOR MANUFACTURING ORIGINAL MASTER

(76) Inventor: Yoshiaki Kojima, Tsurugashima-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 12/447,738

(22) PCT Filed: Nov. 6, 2006
(86) PCT No.: PCT/JP2006/322104

§ 371 Date: Apr. 29, 2009

(51) Int. Cl. G03F 7/20

(52) U.S. Cl. 430/296; 250/492.3

(57) ABSTRACT

An original master manufacturing method of rotating an original master at a constant linear velocity, moving in a plane the original master in a predetermined radial direction at a constant velocity which is provided with a predetermined amount of movement per round of the original master, deflecting the electron beam in the planar movement direction of the original master by a first deflection amount equal to the predetermined movement amount per round of the original master on the surface of the original master during exposure of the concentric circular data patterns corresponding to first through (n−1)-th rounds of each of the plurality of tracks, upon completion of the exposure of the concentric circular data patterns corresponding to the first through (n-1)-th rounds, deflecting the electron beam in a direction opposite to the planar movement direction of the original master by a second deflection amount equal to the predetermined distance on the surface of the original master, and upon completion of exposure of the concentric circular data pattern corresponding to an n-th round of each of the plurality of tracks, deflecting the electron beam in the direction opposite to the planar movement direction of the original master by a third deflection amount on the surface of the original master such that an irradiation position of the electron beam is located at an exposure start position on the concentric circle of a first round of an adjacent track.

### TECHNICAL FIELD

The present invention relates to a method for manufacturing an original master having a plurality of tracks formed thereon by irradiating an electron beam onto the original master having a resist layer on a surface thereof to expose the resist layer.

### BACKGROUND ART

In a conventional process for drawing trains of pits onto concentric circular tracks by irradiating a laser beam onto an original master for optical disks to subject the original master to expose, in the course of one revolution of the original master, a stage that carries the original master is moved in the radial direction of the original master while the beam is deflected in the same direction as the direction of the movement at a uniform rate by the equivalent of the track pitch (see Japanese Patent Application Laid-open Publication No. S63-112839). For example, when pit trains are drawn onto a plurality of tracks through exposure, which is started by irradiating a beam from a starting point A of the first track as shown by arrows in FIG. 1A, by the time that the beam irradiation position reaches the starting point A again by one revolution of the original master, the beam is deflected at a constant rate by a distance of the track pitch as shown in FIG. 1B. The distance of the track pitch corresponds to the movement distance of the stage in the course of one revolution. When the irradiation position of the beam reaches the starting point A, the irradiation position of the beam is immediately shifted through high-speed deflection to a starting point B of the second track positioned in the same radial direction as the starting point A. This beam deflection operation is repeated for each track.

In a magnetic disk such as a hard disk, a concentric circular pattern equivalent to that on optical disks is drawn by an electron beam, in order to record servo patterns indicating position information.

### DISCLOSURE OF THE INVENTION

However, in the magnetic disk, it is necessary to expose patterns having higher degrees of resolution and accuracy for higher densities. Further, since conventional original master manufacturing methods are susceptible to the effects of electron beam stability, there are problems with degradation such as variability of line width and variability of irradiation position.

These are examples of the problems to be solved by the invention and it is an object of the invention to provide an original master manufacturing method capable of exposing concentric circular tracks of high resolution and high accuracy patterns, and a computer-readable program for implementing the method.

An original master manufacturing method of the invention in claim 1 is a method of irradiating an electron beam on an original master having a resist layer on a surface to expose a concentric circular data pattern by n (n is an integer that is equal to or greater than 2) rounds per track at a predetermined distance, so that a plurality of tracks having a predetermined track pitch are formed on the original master, the method comprising: a rotation driving step of rotary-driving the original master at a constant linear velocity; a movement step of moving in a plane the original master in a predetermined radial direction at a constant velocity which is provided with a predetermined amount of movement per round of the original master; a first deflection step of deflecting the electron beam in the planar movement direction of the original master by a first deflection amount equal to the predetermined movement amount per round of the original master on the surface of the original master during exposure of the concentric circular data patterns corresponding to first through (n−1)-th rounds of each of the plurality of tracks; a second deflection step of deflecting the electron beam in a direction opposite to the planar movement direction of the original master by a second deflection amount equal to the predetermined distance on the surface of the original master, upon completion of the exposure of the concentric circular data patterns corresponding to the first through (n−1)-th rounds; and a third deflection step of deflecting the electron beam in the direction opposite to the planar movement direction of the original master by a third deflection amount on the surface of the original master such that an irradiation position of the electron beam is located at an exposure start position on the concentric circle of a first round of an adjacent track, upon completion of exposure of the concentric circular data pattern corresponding to an n-th round of each of the plurality of tracks.

A program of the invention in claim 7 is a program for executing an original master manufacturing method of irradiating an electron beam on an original master having a resist layer on a surface to expose a concentric circular data pattern by n (n is an integer that is equal to or greater than 2) rounds per track at a predetermined distance, so that a plurality of tracks having a predetermined track pitch are formed on the original master, comprising: a rotation driving step of rotary-driving the original master at a constant linear velocity; a movement step of moving in a plane the original master in a predetermined radial direction at a constant velocity which is provided with a predetermined amount of movement per round of the original master; a first deflection step of deflecting the electron beam in the planar movement direction of the original master by a first deflection amount equal to the predetermined movement amount per round of the original master on the surface of the original master during exposure of the concentric circular data patterns corresponding to first through (n−1)-th rounds of each of the plurality of tracks; a second deflection step of deflecting the electron beam in a direction opposite to the planar movement direction of the original master by a second deflection amount equal to the predetermined distance on the surface of the original master, upon completion of the exposure of the concentric circular data patterns corresponding to the first through (n−1)-th rounds; and a third deflection step of deflecting the electron beam in the direction opposite to the planar movement direction of the original master by a third deflection amount on the surface of the original master such that an irradiation position of the electron beam is located at an exposure start position on the concentric circle of a first round of an adjacent track, upon completion of exposure of the concentric circular data pattern corresponding to an n-th round of each of the plurality of tracks.

### BRIEF DESCRIPTION OF THE DRAWINGS

FIGS. 1A and 1B are diagrams showing a conventional original master manufacturing method;

FIG. 2 is a diagram showing a configuration of an electron beam lithography system to which an original master manufacturing method of the present invention is applied;

FIG. 3 is a diagram showing an exposure procedure when forming one track through drawing of four concentric circles by the system of FIG. 2;

FIG. 4 is a flowchart showing operation of a main controller in the system of FIG. 2;

FIGS. 5A and 5B are diagrams showing a spot position and a deflection amount of an electron beam when forming one track through drawing of four concentric circles;

FIG. 6 is a diagram showing a deflection state of the electron beam when four concentric circles are drawn to form one track;

FIG. 7 is a diagram showing a lithography procedure when the system of FIG. 2 is used to form one track through drawing of n concentric circles; and

FIGS. 8A and 8B are diagrams showing a spot position and a deflection amount of the electron beam when n concentric circles are drawn to form one track.

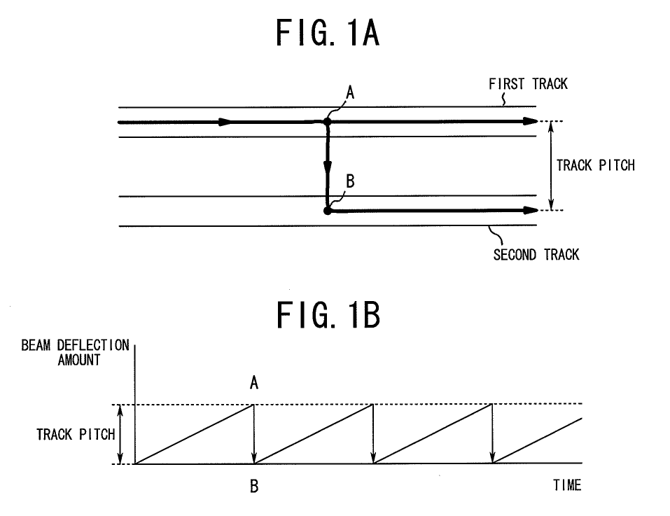

### BEST MODE FOR CARRYING OUT THE INVENTION

According to the original master manufacturing method of the present invention of the first aspect and the program of the present invention of the seventh aspect, in the course of exposing a plurality of concentric circular data patterns to form a single track, the degree to which the electron beam is moved during exposure of the individual concentric circular data patterns can be kept to a lower level than that of movement of the master in a predetermined radial direction during a single revolution, whereby it will be possible for drawing to be performed within a short time, as well as making it possible to expose data pattern tracks with high resolution and high accuracy through utilization of a multiple exposure averaging effect.

### Embodiments

Embodiments of the present invention will be described in detail below with reference to the accompanying drawings.

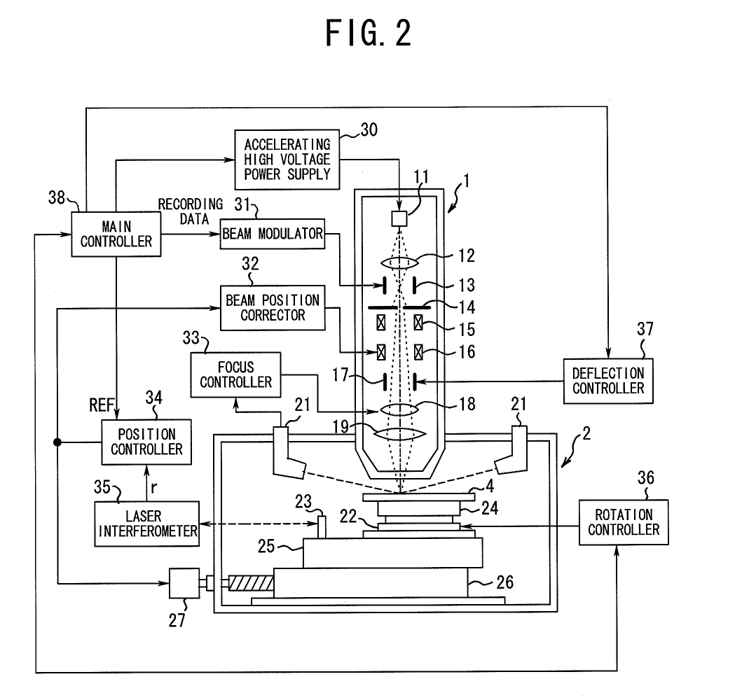

FIG. 2 shows an electron beam lithography system which is applied in a master exposure process of a stamper or exposure mask for producing magnetic disk substrates. The electron beam lithography system comprises an electron column 1, a vacuum chamber 2, and a recording control system 30 through 38.

The electron column 1 is a column-shaped component in which an electron optical system for irradiating an electron beam onto an original master 4, discussed later, inside the vacuum chamber 2 is provided. The optical system inside the electron column 1 is provided with an electron emitter 11, a condenser lens 12, a blanking plate 13, an aperture plate 14, a deflecting coil 15, an alignment coil 16, a high-speed deflector 17, a focus lens 18, and an objective lens 19. These components 11 to 19 are arranged within the electron column 1, in order from the top.

The electron emitter 11 generates an electron beam when a high voltage is applied thereto by an accelerating high voltage power supply 30, discussed later. The condenser lens 12 focuses the electron beam generated by the electron emitter 11 to produce a crossover in the center part of the blanking plate 13. The blanking plate 13 is composed, for example, of electrodes of an electrostatic deflection type adapted to turn on and off the electron beam in response to an output signal of a beam modulator 31, discussed later. The aperture plate 14 is provided with a circular aperture for limiting the electron flux of the electron beam. The deflecting coil 15 changes the traveling direction of the electron beam in response to an output signal from a deflecting circuit, not shown. The alignment coil 16 deflects the electron beam in response to an output signal of a beam position corrector 32. The high-speed deflector 17 deflects the electron beam in a desired direction in response to an output signal of a deflection controller 37. The focus lens 18 performs focus control of the electron beam in response to an output signal of a focus controller 33, and focuses the electron beam onto the master 4 via the objective lens 19.

Within the vacuum chamber 2 there are disposed a height sensor 21, a spindle motor 22, a mirror 23, a turntable 24, a stage 25, and a stage movement mechanism 26. The spindle motor 22 and the mirror 23 are arranged on the stage 25. The spindle motor 22 rotates the turntable 24. The original master 4 is set on the turntable 24. The master 4 may be composed of an electron beam resist layer formed on a substrate of silicon, for example. The stage 25 is capable of being moved in the disk radial direction (X direction) of the original master 4 by the stage movement mechanism 26. With a motor 27 installed as a power source outside of the vacuum chamber 2, the stage movement mechanism 26 performs the movement of the stage 25. The mirror 23 is provided for the purpose of measuring a movement distance of the stage 25 in the disk radial direction. The height sensor 21 is disposed in the upper part inside the vacuum chamber 2 and is adapted to optically sense the height of a recording position of the original master 4.

The recording control system includes the accelerating high voltage power supply 30, the beam modulator 31, the beam position corrector 32, the focus controller 33, a position controller 34, a laser interferometer 35, a rotation controller 36, the deflection controller 37, and a main controller 38.

The accelerating high voltage power supply 30 applies a high voltage to the electron emitter 11 in response to a command from the main controller 38.

The beam modulator 31 supplies a beam modulating signal to the blanking plate 13 in accordance with recording data supplied by the main controller 38.

The focus controller 33 moves the focal position of the beam by the focal lens 18 in response to the recording location height information detected by the height sensor 21.

The laser interferometer 35 irradiates a laser beam to the mirror 23, receives the reflected light of the laser beam, and senses the location of the mirror 23, i.e. movement distance information r relating to the stage 25. The movement distance information r indicates a recording location in the radial direction of the original master 4. The movement distance information r measured by the laser interferometer 35 is supplied to the position controller 34. The position controller 34 then compares the movement distance information r with reference distance information REF, and in response to a position error signal of the comparison result, drives the motor 27 via motor actuating means, not shown. The position error signal is also supplied to the beam position corrector 32. In response to the position error signal from the position controller 34, the beam position corrector 32 excites the alignment coil 16, thereby deflecting the electron beam.

The rotation controller 36 drives rotation of the spindle motor 22 in response to a command from the main controller 38. The deflection controller 37 controls deflection of the electron beam by the high speed deflector 17 in response to a command provided by the main controller 38.

The accelerating high voltage power supply 30, the beam modulator 31, the focus controller 33, a position controller 34, the rotation controller 36, and the deflection controller 37 are each controlled in response to commands of the main controller 38. The main controller 38 may be composed, for example, of a microcomputer, and executes command operations in accordance with a program.

A pattern lithography process carried out by exposure of the original master 4 using the electron beam lithography system having the above configuration will be described. The pattern lithography process involves forming a plurality of tracks at a track pitch 8δx. Each of the plurality of tracks is produced through drawing of four concentric circles. The pitch of the four concentric circles is δx, and width of the track is 4δx.

To record servo zone data and data zone data, the main controller 38 instructs the position controller 34 to set a stage movement to the aforementioned reference distance information REF, and instructs the rotation controller 36 to rotate the spindle motor 22 at a constant rotational linear velocity.

The position controller 34 compares the reference distance information REF with the movement distance information r of the stage 25 output by the laser interferometer 25, and in response to a position error signal of the comparison result, drives the motor 27 via motor actuating means, not shown.

Through these commands and operations, the master 4 is rotated by one rotation along with the turntable 24 by the spindle motor 22, and at the same time is moved in the master radial direction along with the stage 25 by the stage movement mechanism 26. The movement distance of the stage 25 is 2δx per one rotation of the spindle motor 22. 2δx is a distance equivalent to ¼ the track pitch 8δx.

The feed velocity v of the stage 25 is expressed as:

v=(V/2πR)×2δx=Vδx/πR

where V denotes the recording linear velocity and R denotes the radius of the recording location. The main controller 38 changes the reference distance information REF supplied to the position controller 34 in accordance with the feed velocity v. Since the position controller 34 drives the motor 27 while generating a position error signal so as to be equal the movement distance information r and the reference distance information REF to each other. As a result, the stage 25 moves at a constant rate of 2δx per one rotation of the spindle motor 22.

The main controller 38 also instructs the accelerating high voltage power supply 30 to apply voltage to the high voltage electron emitter 11. Thus, an electron beam is generated from the electron emitter 11. Further, The main controller 38 instructs the focus controller 33 to focus the electron beam onto the master 4.

The beam position corrector 32 excites the alignment coil 16 in response to the position error signal from the position controller 34, thereby deflecting the electron beam.

Recording data is supplied at a fixed clock timing from the main controller 38 to the beam modulator 31. The clock timing is in sync with the commands issued to the position controller 34 and the rotation controller 36. The recording data is data indicating servo zone data and data zone data per disk in the order of data recorded. In response to the recording data, the beam modulator 31 generates a modulating signal, and in response to the modulating signal the blanking plate 13 deflects the electron beam generated from the electron emitter 11. Thus, one of the case that the electron beam passes through the aperture of the aperture plate 14 and the other case that the beam does not pass through the aperture is obtained. In the former case, after having passed through the aperture the electron beam is irradiated as a spot onto a recording surface of the master 4 via the deflecting coil 15, the alignment coil 16, the high-speed deflector 17, the focus lens 18, and the objective lens 19. In the latter case, the electron beam does not travel beyond the aperture plate 14 and is not irradiated onto the master 14.

A pattern in the form of a latent image is formed in sections of the master 4 that are irradiated by the electron beam, and the resist layer in the latent image sections is removed in a subsequent developing step. The sections in which the resist layer has been removed is recessed, forming the actual pattern.

In order to form one track for recording data, data of the one track corresponding to one round of the disk is generated repeatedly four times.

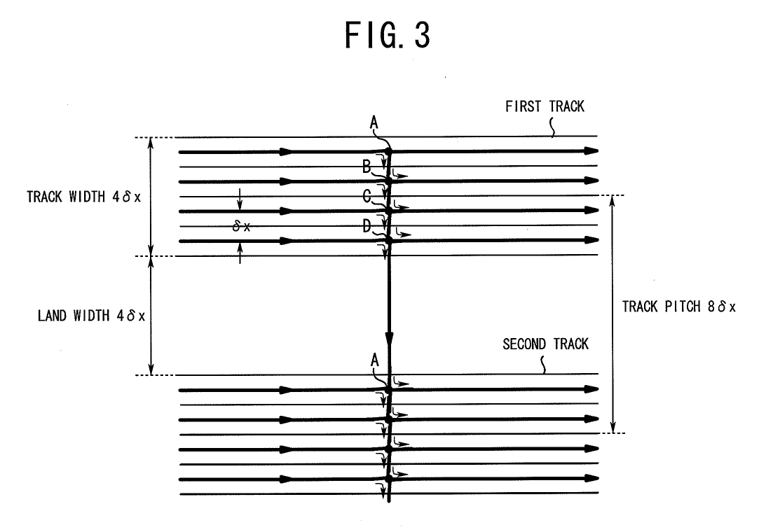

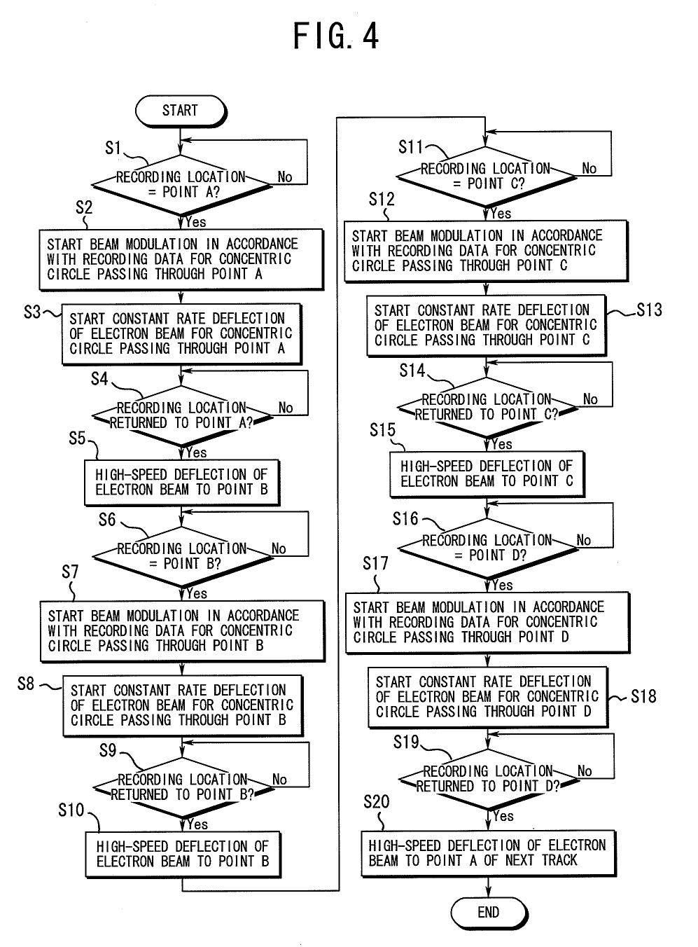

As shown in FIG. 3, when one track is drawn, points situated along the same disk radial direction serving as a reference location on the first track is designated as A, B, C, and D. The points A, B, C, and D are located in the alphabetical order from the inside peripheral side, at intervals of δx. The point A is a recording start point of the first track, and the point D is a recording end point of the first track. The rotation controller 36 drives the spindle motor 22 so as to spin at constant rotational linear velocity. As shown in FIG. 4, to write one track the main controller 38 first determines whether the recording location of the spot (the exposure location) is the location of the point A (Step S1). Movement of the recording location to the point A is accomplished through movement of the stage 25. If the recording location is the location of the point A, the main controller 38 supplies recording data to the beam modulator 31 to start beam modulation (Step S2), and at the same time instructs the deflection controller 37 to perform deflection of the electron beam at a constant rate (Step S3). In response to the constant rate deflection command, the deflection controller 37 deflects the electron beam in the radial direction, namely the inside peripheral direction (first deflection step). On the height plane of the recording face of the master 4 the spot of the beam moves at a velocity equal to the feed velocity v of the stage 25. However, since the master 4 is moving in the same direction at the velocity v, as a result, the spot becomes a stationary state in the radial direction on the master 4, and locates on the concentric circle that passes through the point A. That is, a pattern corresponding to the recording data is sequentially drawn on the concentric circle that passes through the point A, through exposure in the direction indicated by arrows in FIG. 3.

The main controller 38 then determines whether the recording location of the spot has traveled by one round and returned to the point A (Step S4). If the recording location has returned to the point A, the deflection amount of the electron beam at this time point is 2δx, which corresponds to the first deflection amount. The deflection controller 37 is instructed to perform high-speed deflection of the electron beam so that the recording location is at the point B (Step S5). That is, this is the second deflection step, in which the electron beam deflection amount is returned to δx. This deflection amount corresponds to the second deflection amount. A determination id made as to whether the recording location of the spot is the location of the point B (Step S6). If the recording location is the location of the point B, recording data is supplied to the beam modulator 31 to start beam modulation (Step S7), while at the same time the deflection controller 37 is instructed to perform constant rate deflection of the electron beam (Step S8). A pattern corresponding to the same recording data, which is formed on the concentric circle that passes through the points A, is drawn through exposure onto the concentric circle that passes through the point B.

The main controller 38 determines whether the recording location of the spot has traveled by one round and returned to the point B (Step S9). If the recording location has returned to the point B, the deflection amount of the electron beam at this time point is 3Δx. The deflection controller 37 is instructed to perform high-speed deflection of the electron beam so that the recording location is at the point C (Step S10). That is, the deflection amount of the electron beam is 2δx. It is determined whether the recording location of the spot is the location of the point C (Step S11). If the recording location is the location of the point C, recording data is supplied to the beam modulator 31 to start beam modulation (Step S12), while at the same time the deflection controller 37 is instructed to perform constant rate deflection of the electron beam (Step S13). A pattern corresponding to the same recording data, which is formed on the concentric circles that pass through the points A and B, is drawn through exposure onto the concentric circle that passes through the point C.

The main controller 38 then determines whether the recording location of the spot has traveled by one round and returned to the point C (Step S14). If the recording location has returned to the point C, the deflection amount of the electron beam at this point in time is 4δx. The deflection controller 37 is instructed to perform high-speed deflection of the electron beam so that the recording location is now at the point D (Step S15). Specifically, the deflection amount of the electron beam is 3δx. It is determined whether the recording location of the spot is the location of the point D (Step S16). If the recording location is the location of the point D, recording data is supplied to the beam modulator 31 and beam modulation is initiated (Step S17), while at the same time the deflection controller 37 is instructed to perform constant rate deflection of the electron beam (Step S18). A pattern corresponding to the same recording data, which is formed on the concentric circles that pass through the points A, B, and C, is drawn through exposure onto the concentric circle that passes through the point D.

The main controller 38 determines whether the recording location of the spot has traveled by one round and returned to the point D (Step S19). If the recording location has returned to the point D, pattern drawing is completed for the recording data of one track. The deflection amount of the electron beam at this point in time is 5δx. The deflection controller 37 is instructed to perform high-speed deflection of the electron beam so that the recording location is at the point A of the next track (Step S20). This corresponds to the third deflection step, and involves returning the deflection amount of the electron beam equivalent to the third deflection amount 5δx to zero. The operation of above steps S1 through S20 is repeated for the next track.

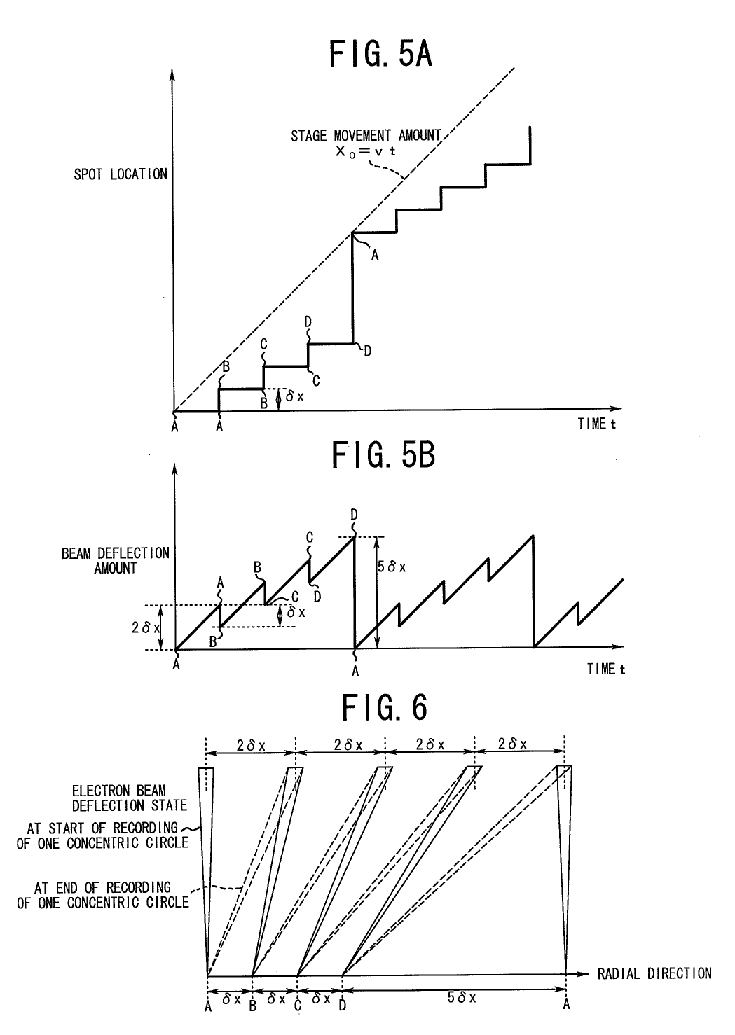

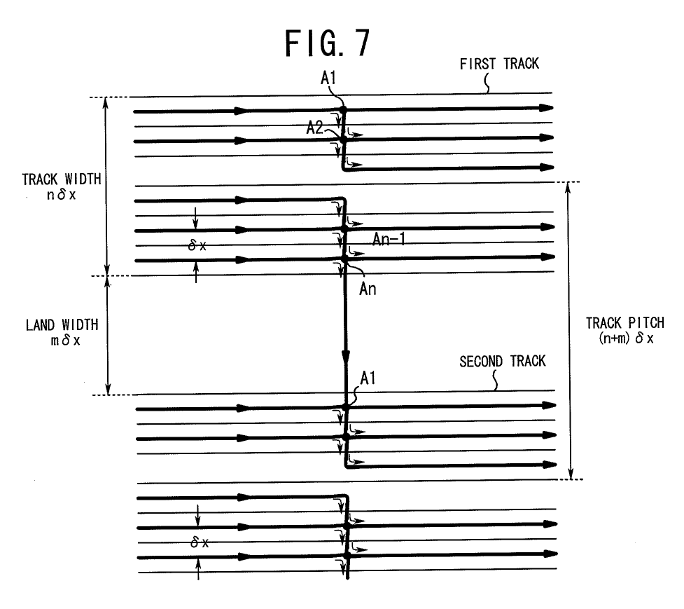

Consequently, the spot location in the radial direction moves over time as shown in FIG. 5A, and the deflection amount of the electron beam on the recording face changes as shown in FIG. 5B. FIG. 6 shows the relationship between the irradiation location and change in the direction of deflection of the electron beam with respect to the master 4. In FIG. 6, the electron beams shown by the solid lines depict the deflection state at the start of recording of each concentric circle, while the electron beams shown by the broken lines depict the deflection state at the completion of recording of each concentric circle. From the drawings it is understood that at the recording start point A, which is the point in time of starting of drawing through exposure for one track, the deflection amount of the electron beam is zero; while at the recording end point D, which is the point in time of completion of drawing, the deflection amount of the electron beam is 5δx. The deflection amount of 5δx is reset to a deflection amount of zero through high-speed deflection. The spot is situated at the recording start point A for the subsequent second track. By repeating this operation for each track, patterns can be drawn on each of the plurality of tracks without carrying out a blanking operation equivalent to the movement amount of the stage between the concentric circles. Since the deflection amount of the electron beam during drawing of one track can be an amount less than the movement amount of the stage (the track pitch), it is possible to carry out drawing within a short time, as well as possible to write concentric circles with high resolution and high accuracy through utilization of a multiple exposure averaging effect.

In the preceding embodiment, one track is produced by drawing concentric circles four times, but it would be acceptable to produce one track by drawing concentric circles a number n of times other than four. In this case, as shown in FIG. 7, where track width is nδx and width of the lands between tracks is mδx, track pitch is (n+m)δx. The feed velocity v of the stage 25 is expressed as:

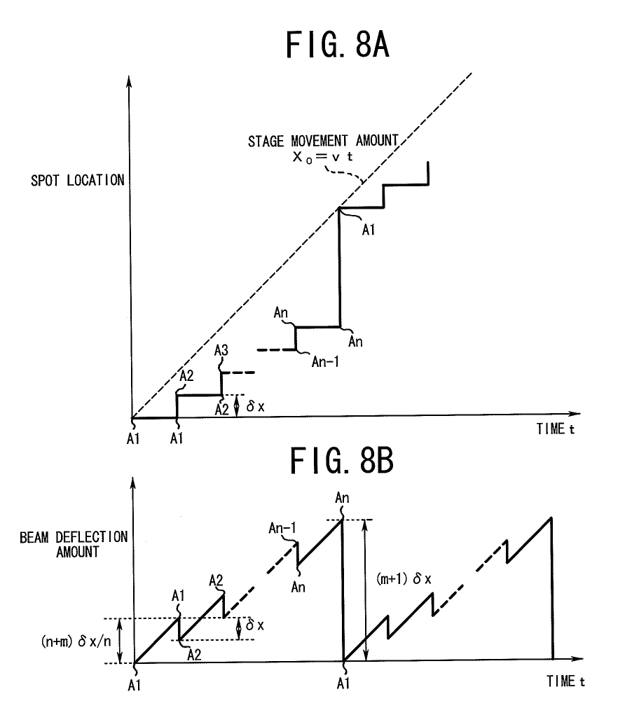

v=(V/2πR)×(n+m)δx/n=Vδx(n+m)/2nπR

where V denotes recording linear velocity and R denotes radius of the recording location. During drawing equivalent to one revolution of the spindle motor 22 from the recording start point A1 back to the start point A1, the deflection amount of the electron beam is (n+m)δx/n. Through high-speed deflection of the electron beam so as to change the recording location from the point A1 to the following point A2, the deflection amount of the electron beam is reduced by δx, to mδx/m. The subsequent deflection amount of the electron beam is comparable, with the spot location in the radial direction shifting over time as shown in FIG. 8A and with the deflection amount of the electron beam on the recording face changing over time as shown in FIG. 8B.

Because the stage movement velocity is proportional to the deflection amount (n+m)δx/n, by setting m to a larger value compared to n, the stage can be moved faster, thus making it possible to shorten drawing time. By shortening the write time, the system is less susceptible to the effects of fluctuations of the electron beam, contributing to improved recording accuracy.

In the preceding embodiments, at the point in time that the beam spot is situated at the recording start point A or A1 for each of the tracks, the deflection amount of the electron beam is zero; however, the beam could have a deflection amount different from zero at the start point.

According to the present invention as set forth above, a plurality of concentric circular data patterns for forming one track are exposed. In the exposure of each of the concentric circular data patterns, during each exposure of the concentric circular data patterns corresponding to the first through (n−1)-th rounds, the electron beam is deflected on the surface of the original master in the direction of planar movement of the master by a first deflection amount per revolution of the master. When the exposure of each of the concentric circular data patterns corresponding to the first through (n−1)-th rounds is completed, the electron beam is deflected by a second deflection amount on the surface of the master. Further, the exposure of the concentric circular data pattern corresponding to the n-th round is completed, the electron beam is deflected by a third deflection amount in the direction opposite to the planar movement direction of the master such that the irradiation position of the electron beam is located at the exposure start position of the first concentric circle of the adjacent track. Thus, the deflection amount of the electron beam is an amount less than the movement amount of the master in a predetermined radial direction during one revolution, whereby it is possible to carry out drawing within a shorter time, as well as to expose data pattern tracks with high resolution and high accuracy through utilization of a multiple exposure averaging effect.

The original master manufacturing method according to the present invention is suitable for data pattern lithography of a master for fabrication of substrates for magnetic disks such as hard disks.

1. An original master manufacturing method of irradiating an electron beam on an original master having a resist layer on a surface to expose a concentric circular data pattern by n (n is an integer that is equal to or greater than 2) rounds per track at a predetermined distance, so that a plurality of tracks having a predetermined track pitch are formed on the original master, the method comprising:
a rotation driving step of rotary-driving the original master at a constant linear velocity;
a movement step of moving in a plane the original master in a predetermined radial direction at a constant velocity which is provided with a predetermined amount of movement per round of the original master;
a first deflection step of deflecting the electron beam in the planar movement direction of the original master by a first deflection amount equal to the predetermined movement amount per round of the original master on the surface of the original master during exposure of the concentric circular data patterns corresponding to first through (n−1)-th rounds of each of the plurality of tracks;
a second deflection step of deflecting the electron beam in a direction opposite to the planar movement direction of the original master by a second deflection amount equal to the predetermined distance on the surface of the original master, upon completion of the exposure of the concentric circular data patterns corresponding to the first through (n−1)-th rounds; and
a third deflection step of deflecting the electron beam in the direction opposite to the planar movement direction of the original master by a third deflection amount on the surface of the original master such that an irradiation position of the electron beam is located at an exposure start position on the concentric circle of a first round of an adjacent track, upon completion of exposure of the concentric circular data pattern corresponding to an n-th round of each of the plurality of tracks.

2. The original master manufacturing method according to claim 1, wherein when the predetermined distance is given by δx (δx is a positive number), a land width between the tracks is given by mδx (m is an integer that is equal to or greater than 1), and the track pitch is given by (n+m)δx, the predetermined movement amount and the first deflection amount are (n+m)δx/n, the second deflection amount is δx, and the third deflection amount is (m+1)δx.

3. The original master manufacturing method according to claim 1, wherein a deflection amount of the electron beam is zero at the exposure start location of the concentric circle corresponding to the first round of each of the plurality of tracks.

4. The original master manufacturing method according to claim 1, wherein upon returning to the exposure start location of each of the concentric circular data patterns corresponding to the first through (n−1)-th rounds, the electron beam is deflected by high-speed deflection in the direction opposite to the planar movement direction of the original master by the second deflection amount equal to the predetermined distance on the surface of the original master in the second deflection step.

5. The original master manufacturing method according to claim 1, wherein upon returning to the exposure start location of the concentric circular data pattern corresponding to the n-th round, the electron beam is deflected by high-speed deflection in the direction opposite to the planar movement direction of the original master by the third deflection amount on the surface of the original master in the third deflection step.

6. The original master manufacturing method according to claim 1, wherein the exposure start location of each of the concentric circular data patterns corresponding to the first through n-th rounds is located in a same radial direction of the original master.

7. A computer-readable program for executing an original master manufacturing method of irradiating an electron beam on an original master having a resist layer on a surface to expose a concentric circular data pattern by n (n is an integer that is equal to or greater than 2) rounds per track at a predetermined distance, so that a plurality of tracks having a predetermined track pitch are formed on the original master, comprising:
a rotation driving step of rotary-driving the original master at a constant linear velocity;
a movement step of moving in a plane the original master in a predetermined radial direction at a constant velocity which is provided with a predetermined amount of movement per round of the original master;
a first deflection step of deflecting the electron beam in the planar movement direction of the original master by a first deflection amount equal to the predetermined movement amount per round of the original master on the surface of the original master during exposure of the concentric circular data patterns corresponding to first through (n−1)-th rounds of each of the plurality of tracks;
a second deflection step of deflecting the electron beam in a direction opposite to the planar movement direction of the original master by a second deflection amount equal to the predetermined distance on the surface of the original master, upon completion of the exposure of the concentric circular data patterns corresponding to the first through (n−1)-th rounds; and
a third deflection step of deflecting the electron beam in the direction opposite to the planar movement direction of the original master by a third deflection amount on the surface of the original master such that an irradiation position of the electron beam is located at an exposure start position on the concentric circle of a first round of an adjacent track, upon completion of exposure of the concentric circular data pattern corresponding to an n-th round of each of the plurality of tracks.

8. An electron beam lithography system for irradiating an electron beam on an original master having a resist layer on a surface to expose a concentric circular data pattern by n (n is an integer that is equal to or greater than 2) rounds per track at a predetermined distance, so that a plurality of tracks having a predetermined track pitch are formed on the original master, the system comprising:
a rotation driving portion which rotary-drives the original master at a constant linear velocity;
a movement portion which moves in a plane the original master in a predetermined radial direction at a constant velocity which is provided with a predetermined amount of movement per round of the original master;
a first deflection portion which deflects the electron beam in the planar movement direction of the original master by a first deflection amount equal to the predetermined movement amount per round of the original master on the surface of the original master during exposure of the concentric circular data patterns corresponding to first through (n−1)-th rounds of each of the plurality of tracks;
a second deflection portion which deflects the electron beam in a direction opposite to the planar movement direction of the original master by a second deflection amount equal to the predetermined distance on the surface of the original master, upon completion of the exposure of the concentric circular data patterns corresponding to the first through (n−1)-th rounds; and
a third deflection portion which deflects the electron beam in the direction opposite to the planar movement direction of the original master by a third deflection amount on the surface of the original master such that an irradiation position of the electron beam is located at an exposure start position on the concentric circle of a first round of an adjacent track, upon completion of exposure of the concentric circular data pattern corresponding to an n-th round of each of the plurality of tracks.

9. The electron beam lithography system according to claim 8, wherein the first through third deflection portions each deflect the electron beam by a same high-speed deflector.
